(19) United States
(12) Patent Application Publication
(10) Pub. No.: US 2025/0293664 A1
(43) Pub. Date: Sep. 18, 2025

(54) PACKAGING OF SURFACE ACOUSTIC WAVE DEVICE HAVING MULTILAYER PIEZOELECTRIC SUBSTRATE

(71) Applicant: SKYWORKS SOLUTIONS, INC., Irvine, CA (US)

(72) Inventors: Rei Goto, Osaka-Shi (JP); Takashi Inoue, Singapore (SG); Alan Sangone Chen, Leesburg, FL (US)

(21) Appl. No.: 19/076,126

(22) Filed: Mar. 11, 2025

Related U.S. Application Data
(60) Provisional application No. 63/564,199, filed on Mar. 12, 2024.

(51) Int. Cl. H03H 9/10; H03H 3/08; H03H 9/02

(52) U.S. Cl. CPC H03H 9/1092; H03H 3/08; H03H 9/02834; H03H 9/02897

(57) ABSTRACT

Aspects and embodiments disclosed herein include a packaged surface acoustic wave device comprising a substrate including a layer of piezoelectric material, a surface acoustic wave resonator including interdigital transducer (IDT) electrodes having interdigitated electrode fingers disposed on a surface of the piezoelectric material layer, and a polymer roof disposed above an upper surface of the layer of piezoelectric material and defining an air cavity in which the surface acoustic wave resonator is disposed, an upper wall of the polymer roof on a side of the polymer roof opposite the surface acoustic wave resonator including a plurality of slits to reduce generation of stress within the packaged surface acoustic wave device resulting from changes in temperature.

### CROSS-REFERENCE TO RELATED APPLICATIONS

This application claims priority under 35 U.S.C. § 119(e) to U.S. Provisional Patent Application Ser. No. 63/564,199, titled “PACKAGING OF SURFACE ACOUSTIC WAVE DEVICE HAVING MULTILAYER PIEZOELECTRIC SUBSTRATE,” filed Mar. 12, 2024, the entire content of which is incorporated herein by reference for all purposes.

### BACKGROUND

### Technical Field

Embodiments of this disclosure relate to packaging of acoustic wave devices with improved reliability.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front-end of a mobile phone can include acoustic wave filters. Two acoustic wave filters can be arranged as a duplexer.

### SUMMARY

In accordance with one aspect, there is provided a packaged surface acoustic wave device. The packaged surface acoustic wave device comprises a substrate including a layer of piezoelectric material, a surface acoustic wave resonator including interdigital transducer (IDT) electrodes having interdigitated electrode fingers disposed on a surface of the piezoelectric material layer, and a polymer roof disposed above an upper surface of the layer of piezoelectric material and defining an air cavity in which the surface acoustic wave resonator is disposed, an upper wall of the polymer roof on a side of the polymer roof opposite the surface acoustic wave resonator including a plurality of slits to reduce generation of stress within the packaged surface acoustic wave device resulting from changes in temperature.

In some embodiments, the substrate is a multilayer piezoelectric substrate.

In some embodiments, the substrate include a support layer formed of silicon.

In some embodiments, the polymer roof is formed of polyimide.

In some embodiments, the polymer roof is formed of polyimide with a silica filler.

In some embodiments, the polymer roof has a thickness of between 50 μm and 100 μm.

In some embodiments, the plurality of slits have depths of between 20 μm and 50 μm but do not pass entirely through the polymer roof.

In some embodiments, the substrate has a thickness of between 130 μm and 200 μm.

In some embodiments, the plurality of slits have widths of between 1 μm and 20 μm.

In some embodiments, the plurality of slits have widths of between 5 μm and 10 μm.

In some embodiments, the plurality of slits occupy up to 20% of a surface area of the polymer roof.

In some embodiments, the plurality of slits are arranged in a grid pattern.

In some embodiments, the plurality of slits include a first plurality of slits extending parallel to a first edge of the substrate and a second plurality of slits extending parallel to a second edge of the substrate and in a direction perpendicular to the first plurality of slits.

In some embodiments, the polymer roof is formed of a material having a coefficient of thermal expansion that is an order of magnitude greater than a coefficient of thermal expansion of a material forming the substrate.

In some embodiments, the packaged acoustic wave device is included in a radio frequency filter.

In some embodiments, the radio frequency filter is included in an electronics module.

In some embodiments, the electronics module is included in an electronic device.

In accordance with another aspect, there is provided a method of packaging an acoustic wave device including interdigital transducer electrodes disposed on an upper surface of a layer of piezoelectric material. The method comprises forming a polymer roof on the upper surface of the layer of piezoelectric material, the polymer roof defining air cavities about the acoustic wave device, and forming a plurality of slits in a side of the polymer roof opposite the layer of piezoelectric material.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2 is a cross-sectional view of an example of a surface acoustic wave resonator including a multilayer piezoelectric substrate;

FIG. 3 illustrates an example of a flip-chip package for a surface acoustic wave resonator;

FIG. 4A illustrates results of a simulation of change in shape of a flip-chip package for a surface acoustic wave resonator with change in temperature;

FIG. 4B illustrates results of a simulation of change in shape of another flip-chip package for a surface acoustic wave resonator with change in temperature;

FIG. 4C illustrates results of a simulation of change in shape of a flip-chip package for a surface acoustic wave resonator as disclosed herein with change in temperature;

FIG. 5 is a schematic diagram of a radio frequency ladder filter;

FIG. 6 is a block diagram of one example of a filter module that can include one or more surface acoustic wave resonators according to aspects of the present disclosure;

FIG. 7 is a block diagram of one example of a front-end module that can include one or more filter modules according to aspects of the present disclosure; and

FIG. 8 is a block diagram of one example of a wireless device including the front-end module of FIG. 7.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

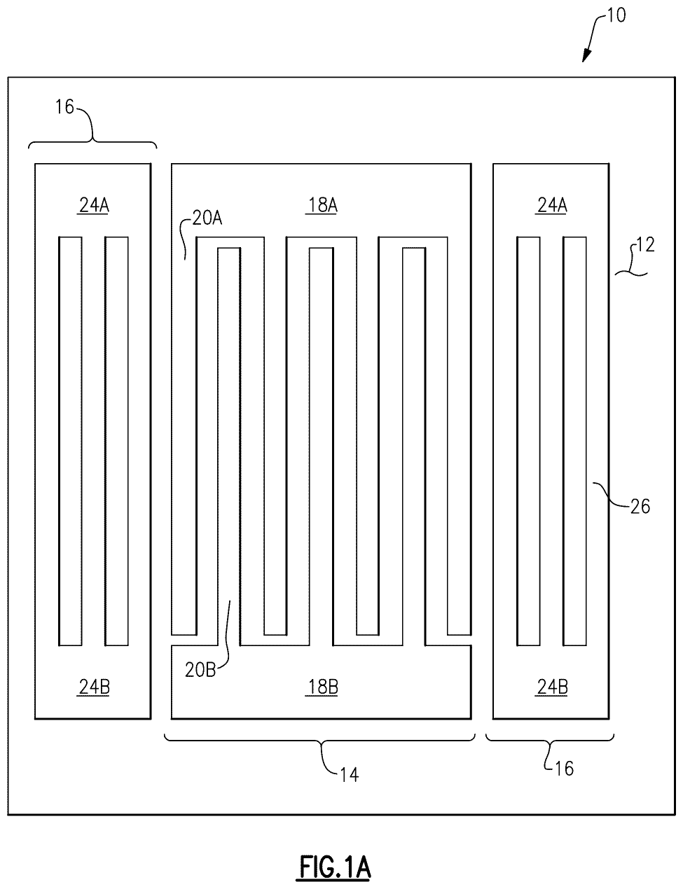

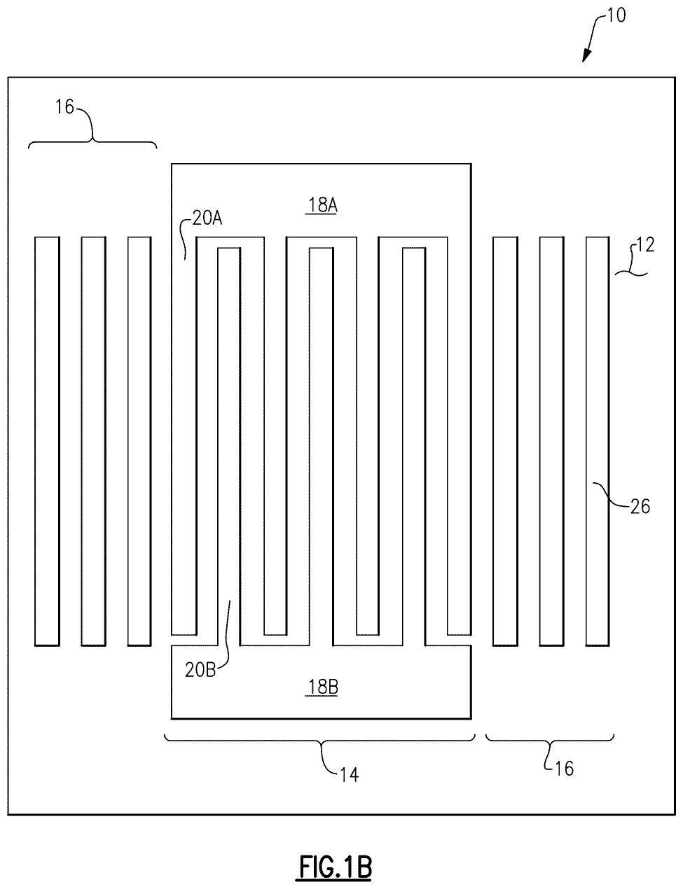

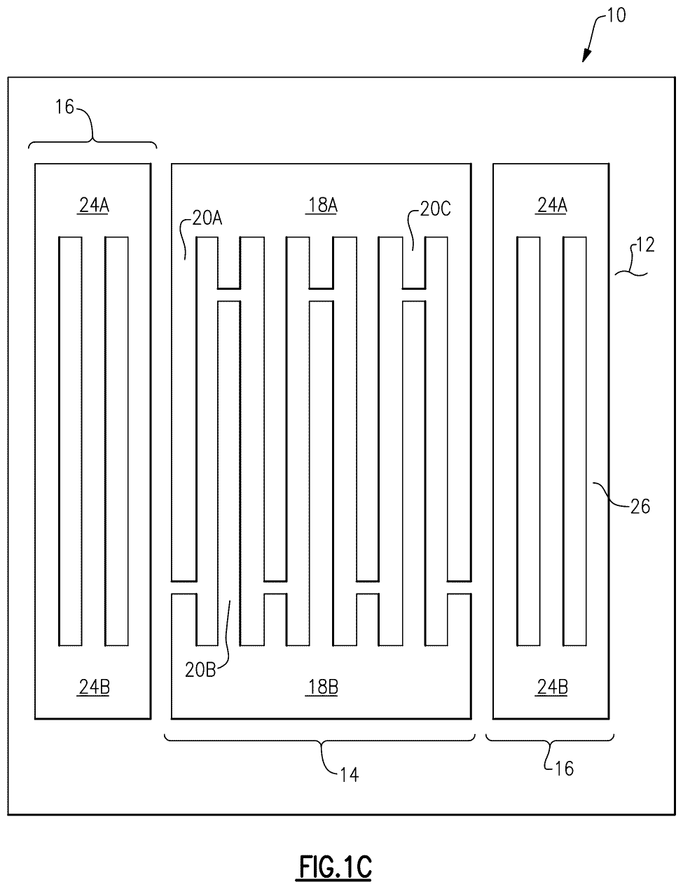

FIG. 1A is a plan view of a surface acoustic wave (SAW) resonator 10 such as might be used in a SAW filter, duplexer, etc.

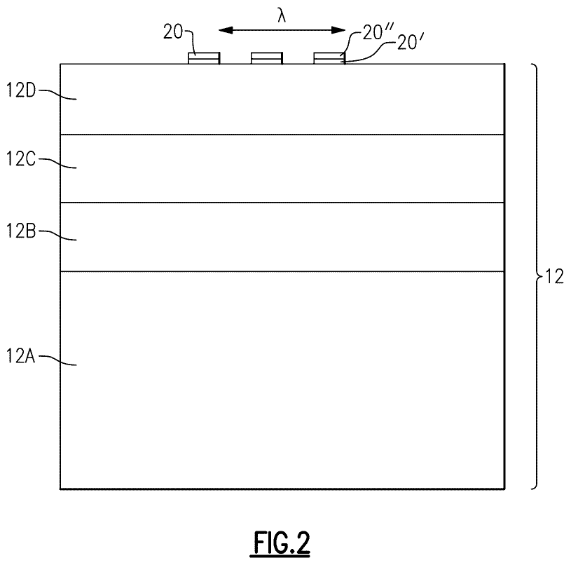

Acoustic wave resonator 10 is formed on a substrate 12 including a piezoelectric material layer, for example, a lithium tantalate (LiTaO₃) or lithium niobate (LiNbO₃) material layer. In some embodiments, as described with reference to FIG. 2 below, the substrate 12 may be a multilayer piezoelectric substrate (MPS). The acoustic wave resonator 10 includes Interdigital Transducer (IDT) electrodes 14 and reflector electrodes 16. In use, the IDT electrodes 14 excite a main acoustic wave having a wavelength λ along a surface of the substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing the first bus bar electrode 18A. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B and reflector fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector fingers 26 may be electrically unconnected. Further, as illustrated in FIG. 1C, acoustic wave resonators as disclosed herein may include dummy electrode fingers 20C that are aligned with respective electrode fingers 20A, 20B. Each dummy electrode finger 20C extends from the opposite bus bar electrode 18A, 18B than the respective electrode finger 20A, 20B with which it is aligned.

It should be appreciated that the acoustic wave resonators 10 illustrated in FIGS. 1A-1C, as well as the other circuit elements illustrated in other figures presented herein, are illustrated in a highly simplified form. The relative dimensions of the different features are not shown to scale. Further, typical acoustic wave resonators would commonly include a far greater number of electrode fingers and reflector fingers than illustrated. Typical acoustic wave resonators or filter elements may also include multiple IDT electrodes sandwiched between the reflector electrodes.

FIG. 2 illustrates a cross-section of the substrate 12 and electrodes 20 that may be utilized in surface acoustic wave devices, for example, as illustrated in any of FIGS. 1A-1C above. The electrodes 20 of FIG. 2 may be any of the IDT electrodes 20A, 20B, the dummy electrodes 20C, or the reflector electrodes 26 of a surface acoustic wave device, for example, as illustrated in any of FIGS. 1A-1C above. The electrodes 20 will, however, be referred to herein as IDT electrodes 20. The IDT electrodes 20 may be multi-layer electrodes including a lower layer 20′ of a first metal and an upper layer 20″ of a second metal that is different from the first metal.

The substrate 12 is a MPS substrate including a support layer 12A that may be formed of any of Si, quartz, sapphire, or any other suitable material to provide the substrate 12 with a desired amount of mechanical stability. A trap-rich layer 12B formed of, for example, polysilicon is disposed on top of the support layer 12A and helps to reduce generation of parasitic currents at the upper surface of the support layer 12A. A layer 12C of a dielectric material, for example, a 600 nm thick layer of SiO₂ is disposed on the upper surface of the trap-rich layer 12B. Layer 12C may be referred to herein as a first functional layer. A layer 12D of a piezoelectric material, for example, a 1,000 nm thick layer of lithium tantalate (LiTaO₃) or lithium niobate (LiNbO₃) is disposed on the upper surface of the layer 12C of dielectric material. The IDT electrodes 20 are disposed on the upper surface of the layer 12D of piezoelectric material. The piezoelectric material of layer 12D may exhibit a negative temperature coefficient of frequency. This may be compensated for by the positive temperature coefficient of frequency exhibited by the SiO₂ in the first functional layer 12C.

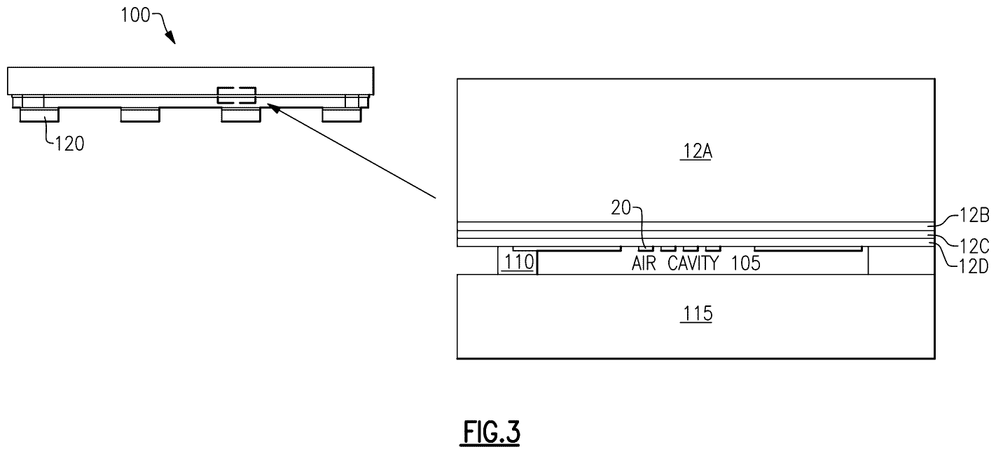

Acoustic wave resonators are often disposed in a package that allows them to be mounted on a circuit board in electrical communication with other elements of an electronic module or device. FIG. 3 illustrates a flip-chip form of package, indicated generally at 100. In the flip-chip package the resonator 10 is inverted from the orientation illustrated in FIG. 2. An air cavity 105 is defined above the resonator structure by, for example, polymer posts 110 and roof 115 (shown on the bottom of the package in FIG. 3 because the package is inverted for flip-chip mounting). The polymer roof 115 protects the resonator 10 from the environment while the air cavity 105 allows for the IDT electrodes 20 to vibrate. Electrical contacts 120, sometimes formed of a metal such as copper and/or solder pass through portions of the polymer roof 115 to provide electrical connection between the resonator and circuitry external to the package 100. The electrical contacts 120 are used to mechanically and electrically connect the package 100 to a circuit board with other electrical components. In various embodiments, the polymer used to form the posts 110 and roof 115 is a polymer having a low thermal coefficient of expansion, for example, polyimide.

One problem that has been observed with acoustic wave resonator packages as illustrated in FIG. 3 is that the polymer used to form the roof 115 typically has a different coefficient of thermal expansion than the substrate 12. The coefficient of thermal expansion of the substrate 12 is dominated by that of the silicon support layer 12A that may have a coefficient of thermal expansion of between about 2.5 ppm/° C. and 3.3 ppm/° C. The coefficient of thermal expansion of polyimide is an order of magnitude higher than this, ranging from 30 ppm/° C. to 60 ppm/° C. This difference in coefficients of thermal expansion between the two different portions of the package 100 may cause stresses within the package if it is thermally cycled, for example, if a device utilizing the resonator 10 is powered on and then off. These stresses may lead to reliability concerns, for example, delamination of the contacts 120 from a circuit board they are connected to or even cracking of the substrate 12.

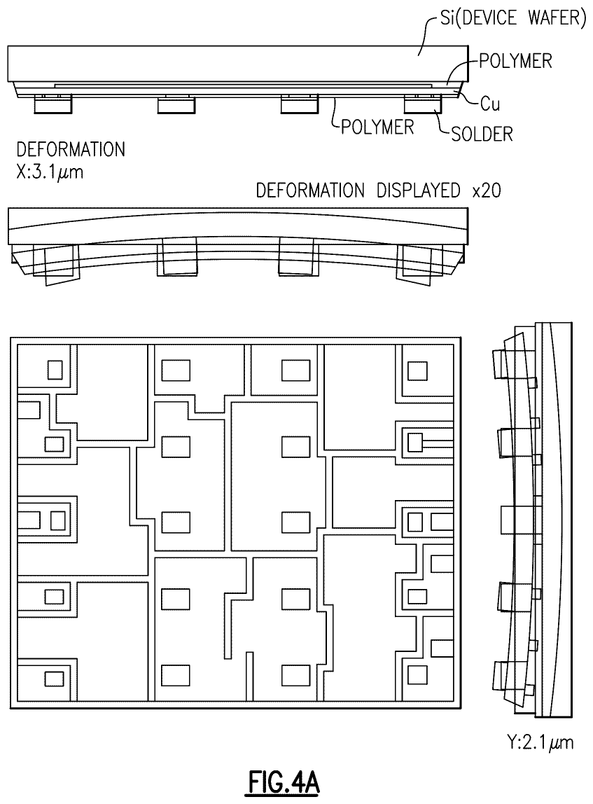

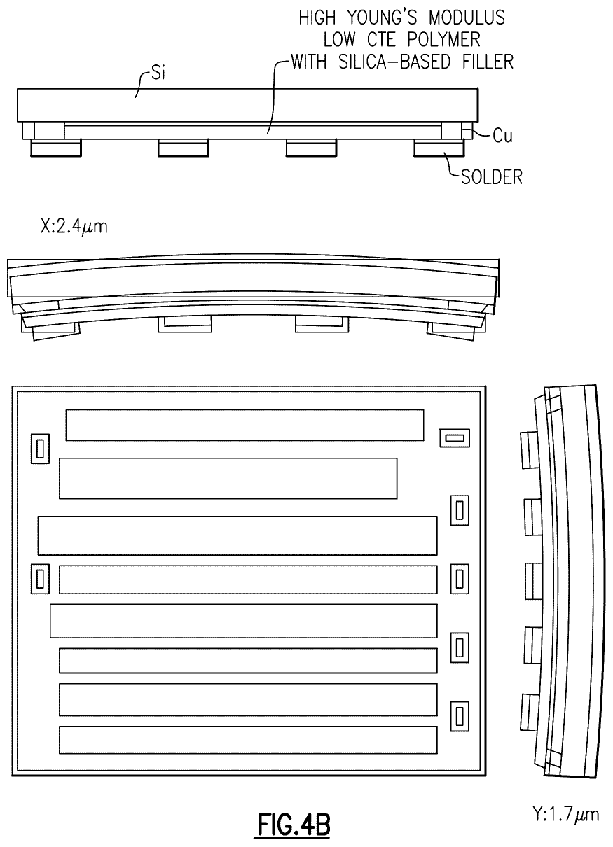

A simulation performed on a package such as illustrated in FIG. 3 having a simulated resonator die size of 1720 μm (x-axis)×1420 μm (y-axis) is shown in FIG. 4A. This simulation assumed the package was not adhered to any circuit board so that change in shape of the package rather than stress was simulated as a function of change in temperature. The temperature was simulated as changing from 150° C. to −65° C. Results of the simulation showed that the x-axis edges of the die would be displaced downward (the polymer side) by 3.1 μm and the y-axis edges of the die would be displaced downward by 2.1 μm.

The simulation was repeated with simulated silica-based particle filler added to the polymer layer to decrease its overall coefficient of thermal conductivity. The results, shown in FIG. 4B, indicated that the displacement of the x-axis edges of the die decreased to 2.4 μm and the displacement of the y-axis edges of the die decreased to 1.7 μm.

The inventor has discovered that it is possible to reduce the displacement of edges of the die with changes in temperature, or, equivalently, to reduce stresses generated in the package or die with changes in temperature when the package is adhered to a circuit board, by cutting slits in the polymer roof of the package. The slits may have widths of from 1 μm to 20 μm or from 5 μm to 10 μm and depths of between 20 μm and 50 μm as compared to a polymer roof thickness of 50 μm to 100 μm and a substrate thickness of 130 μm to 200 μm. The slits, however, should not pass entirely through the polymer roof so the resonator remains protected from the environment. In some embodiments, the slits may occupy up to 20% of the total surface area of the polymer roof. A plurality of slits could be formed extending across the polymer roof in the x and y axes in a grid-like pattern, although other patterns, for example, diagonally arranged slits or slits arranged in patterns of various geometric shapes (square, hexagon, oval, circular, etc.) could also be utilized. In one simulation, the addition of the slits to the polymer with the silica filler used in the simulation with the results shown in FIG. 4B resulted in a further decrease in displacement of the x-axis edges of the die to 2.0 μm and a decrease in the displacement of the y-axis edges of the die to 1.1 μm as illustrated in FIG. 4C, in which four x-axis oriented slits and three y-axis oriented slits are shown.

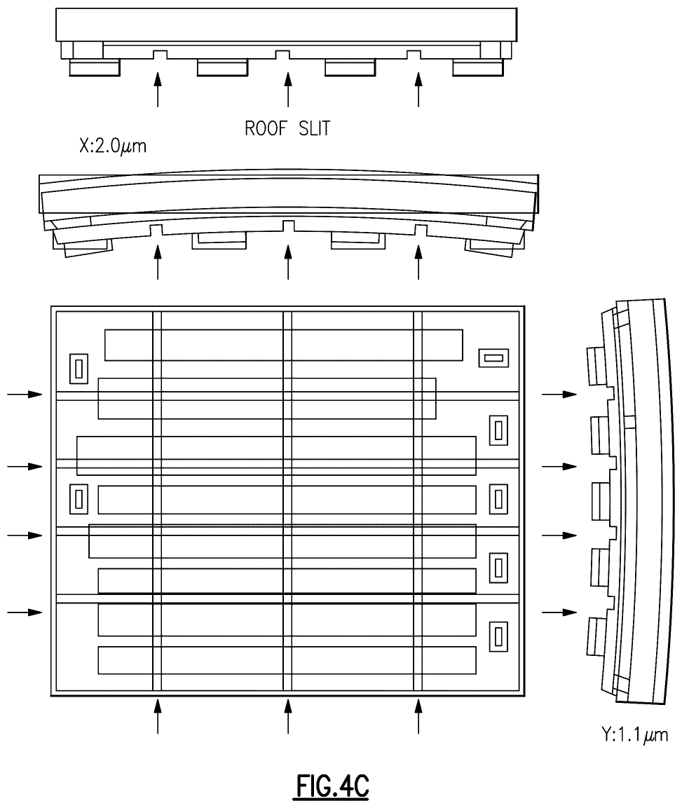

In some embodiments, multiple packaged SAW resonators as disclosed herein may be combined into a filter, for example, an RF ladder filter schematically illustrated in FIG. 5 and including a plurality of series resonators R1, R3, R5, R7, and R9, and a plurality of parallel resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

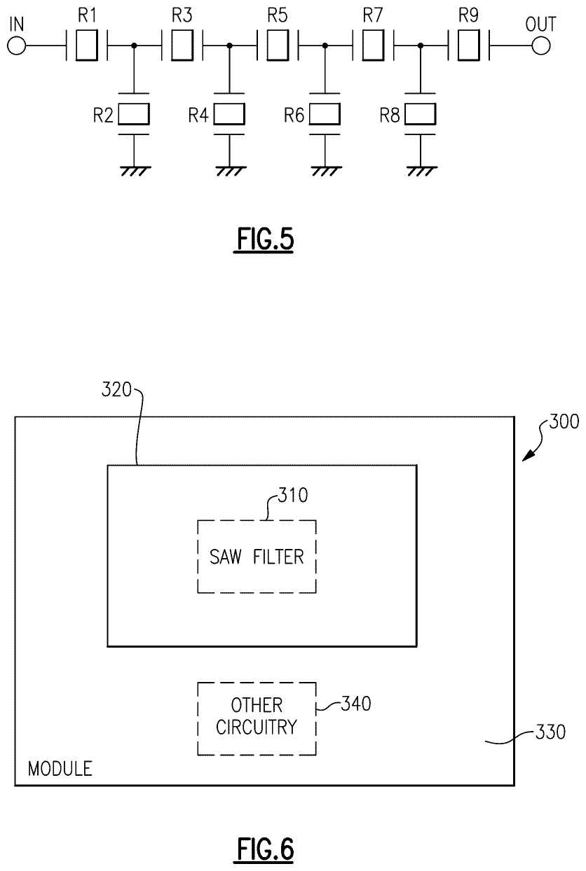

Packaged acoustic wave resonators as discussed herein can be implemented in a variety of packaged modules. Some example packaged modules will now be discussed in which any suitable principles and advantages of the packaged acoustic wave resonators discussed herein can be implemented. FIGS. 6, 7, and 8 are schematic block diagrams of illustrative packaged modules and devices according to certain embodiments.

As discussed above, embodiments of the packaged surface acoustic wave resonators can be configured as or used in filters, for example. In turn, a surface acoustic wave (SAW) filter using one or more surface acoustic wave resonators may be incorporated into and packaged as a module that may ultimately be used in an electronic device, such as a wireless communications device, for example. FIG. 6 is a block diagram illustrating one example of a module 300 including a SAW filter 310. The SAW filter 310 may be implemented on one or more die(s) 320. The die 320 may include a multilayer piezoelectric substrate as illustrated in FIGS. 2 and 3 above. The packaged module 300 includes a packaging substrate 330 that is configured to receive a plurality of components, including the die 320. The die 320 may be flip-chip mounted on the packaging substrate 330. The module 300 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 300 can also include one or more packaging structures to, for example, provide protection and facilitate easier handling of the module 300. Such a packaging structure can include an overmold formed over the packaging substrate 330 and dimensioned to substantially encapsulate the various circuits and components thereon.

Various examples and embodiments of the SAW filter 310 can be used in a wide variety of electronic devices. For example, the SAW filter 310 can be used in an antenna duplexer, which itself can be incorporated into a variety of electronic devices, such as RF front-end modules and communication devices.

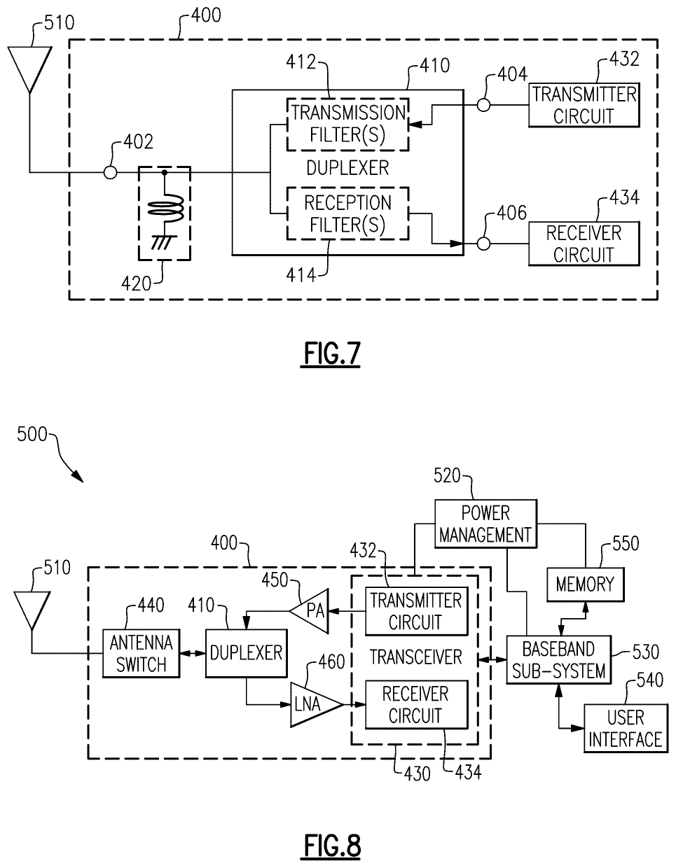

Referring to FIG. 7, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the SAW filter 310 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 7, however in other embodiments these components may be integrated into a common transceiver circuit or module. As will be appreciated by those skilled in the art, the front-end module 400 may include other components that are not illustrated in FIG. 7 including, but not limited to, switches, electromagnetic couplers, amplifiers, processors, and the like.

FIG. 8 is a block diagram of one example of a wireless device 500 including the antenna duplexer 410 shown in FIG. 7. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 7. The front-end module 400 includes the duplexer 410, as discussed above. In the example shown in FIG. 8 the front-end module 400 further includes an antenna switch 440, which can be configured to switch between different frequency bands or modes, such as transmit and receive modes, for example. In the example illustrated in FIG. 8, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 7.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a silicon substrate using complementary metal-oxide semiconductor (CMOS) field effect transistors.

Still referring to FIG. 8, the front-end module 400 may further include a low noise amplifier module 460, which amplifies received signals from the antenna 510 and provides the amplified signals to the receiver circuit 434 of the transceiver 430.

The wireless device 500 of FIG. 8 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A packaged surface acoustic wave device comprising:
a substrate including a layer of piezoelectric material;
a surface acoustic wave resonator including interdigital transducer (IDT) electrodes having interdigitated electrode fingers disposed on a surface of the layer of piezoelectric material; and
a polymer roof disposed above an upper surface of the layer of piezoelectric material and defining an air cavity in which the surface acoustic wave resonator is disposed, an upper wall of the polymer roof on a side of the polymer roof opposite the surface acoustic wave resonator including a plurality of slits to reduce generation of stress within the packaged surface acoustic wave device resulting from changes in temperature.

2. The packaged surface acoustic wave device of claim 1 wherein the substrate is a multilayer piezoelectric substrate.

3. The packaged surface acoustic wave device of claim 2 wherein the substrate include a support layer formed of silicon.

4. The packaged surface acoustic wave device of claim 1 wherein the polymer roof is formed of polyimide.

5. The packaged surface acoustic wave device of claim 1 wherein the polymer roof is formed of polyimide with a silica filler.

6. The packaged surface acoustic wave device of claim 1 wherein the polymer roof has a thickness of between 50 μm and 100 μm.

7. The packaged surface acoustic wave device of claim 6 wherein the plurality of slits have depths of between 20 μm and 50 μm but do not pass entirely through the polymer roof.

8. The packaged surface acoustic wave device of claim 6 wherein the substrate has a thickness of between 130 μm and 200 μm.

9. The packaged surface acoustic wave device of claim 1 wherein the plurality of slits have widths of between 1 μm and 20 μm.

10. The packaged surface acoustic wave device of claim 9 wherein the plurality of slits have widths of between 5 μm and 10 μm.

11. The packaged surface acoustic wave device of claim 1 wherein the plurality of slits occupy up to 20% of a surface area of the polymer roof.

12. The packaged surface acoustic wave device of claim 1 wherein the plurality of slits are arranged in a grid pattern.

13. The packaged surface acoustic wave device of claim 1 wherein the plurality of slits include a first plurality of slits extending parallel to a first edge of the substrate and a second plurality of slits extending parallel to a second edge of the substrate and in a direction perpendicular to the first plurality of slits.

14. The packaged surface acoustic wave device of claim 1 wherein the polymer roof is formed of a material having a coefficient of thermal expansion that is an order of magnitude greater than a coefficient of thermal expansion of a material forming the substrate.

15. A radio frequency filter comprising the packaged surface acoustic wave device of claim 1.

16. An electronics module comprising the radio frequency filter of claim 15.

17. An electronic device including the electronics module of claim 16.

18. A method of packaging an acoustic wave device including interdigital transducer electrodes disposed on an upper surface of a layer of piezoelectric material, the method comprising:
forming a polymer roof on the upper surface of the layer of piezoelectric material, the polymer roof defining air cavities about the acoustic wave device; and
forming a plurality of slits in a side of the polymer roof opposite the layer of piezoelectric material.
